(19) United States
(12) Patent Application Publication
(10) Pub. No.: US 2020/0247038 A1
(43) Pub. Date: Aug. 6, 2020

(54) Digital Projection System for the Development of Photolithography Devices

(71) Applicants: Jesse Aaron Roll, West Lafayette, IN (US); Xinyan Deng, Lafayette, IN (US)

(72) Inventors: Jesse Aaron Roll, West Lafayette, IN (US); Xinyan Deng, Lafayette, IN (US)

(21) Appl. No.: 16/264,133

(22) Filed: Jan. 31, 2019

(51) Int. Cl. B29C 64/129; G03F 7/20; B29C 64/20; B33Y 10/00; B33Y 30/00

(52) U.S. Cl. CPC B29C 64/129; G03F 7/2051; B33Y 50/02; B33Y 10/00; B33Y 30/00; B29C 64/20

(57) ABSTRACT

A novel digital projection system, used to build multi-dimensional structures by the process of photolithography, is presented herein. An exemplary embodiment of the digital projection system describes a process by which multi-dimensional structures are constructed using a layer or series of layers of polymerized light sensitive material. Attributes of this digital projection system offer several enhancements over traditional approaches. The use of the digitally projected images and light sensitive material both eliminates the need for single-use masks and moves the process outside of traditional fabrication environment. Further, through the use of various optic systems, digitally projected images can be scaled to accommodate the construction of multi-dimensional structures spanning the spatial ranges of devices employing the photolithography process and permits for numerous application specific embodiments of the digital projection system described herein.

### CROSS-REFERENCE TO RELATED APPLICATIONS

The present U.S. patent application is related to and claims the priority benefit of U.S. Provisional Patent Application Ser. No. 62/624,172, filed Jan. 31, 2018.

### TECHNICAL FIELD

The present disclosure generally relates to process of photolithography, and in particular to automated systems using digital image projection to build multi-dimensional structures using the process of photolithography.

### BACKGROUND

The process of the photolithography is nowadays commonly found in various applications. Such processes include the use of the clean room environments, imploring spin-coating techniques of light sensitive materials onto substrates in the fabrication of microchips or MEMs devices. Other such examples included the use of dry photoresist films laminated onto substrates, often in near clean room environments, in the fabrication of microfluidic channels on a chip (i.e. “lab-on-a-chip” devices) or printed circuit boards (PCBs). In these applications, with few exceptions, the development of two- or three-dimensional structures through the use photolithography requires the use of task specific, single-use, light masks, shielding areas of the light sensitive material from exposure and preventing polymerization. Alternatively, the use of digitally projected images eliminates the need for single-use masks and when paired with various optic systems is capable of spanning the spatial ranges of applications enumerated above. So far, no fully automated desktop digital projection system exists with the flexibility to address such challenges.

### BRIEF SUMMARY

This patent application describes the use of digital projection system to build multi-dimensional structures using a layer or series of layers of polymerized light sensitive material. The digital projection system incorporates, but is not limited to, the use of at least one of the following subsystems: digital image projector, digital alignment camera, optics assembly, regulated heating coil, vacuum pump, linear stage, computer/controller with wired/wireless connectivity, power supply, and additional electronics required to operate the system for its intended purpose. A proprietary software package is used to convert multi-dimensional computer aided designs into a single file providing images and an instruction set to interface and control the digital projection system.

### BRIEF DESCRIPTION OF DRAWINGS

FIG. 1A is a frontal perspective schematic view of an embodiment of the digital projection system with the embodiment's subsystems labeled.

FIG. 1B is a rearward perspective schematic view of an embodiment of the digital projection system with the embodiment's subsystems labeled.

FIG. 2 is a schematic of the components of an exemplary embodiment of the bonded substrate.

FIG. 3 is a schematic of the components of an exemplary embodiment of the regulated heating coil and vacuum pump subsystem.

FIG. 4A is a rearward perspective schematic view of the components of an exemplary embodiment of the linear stage subsystem.

FIG. 4B is a frontal perspective schematic view of the components of an exemplary embodiment of the linear stage subsystem.

FIG. 5 is an illustration of a frontal perspective schematic view of the digital image alignment location process and projection process of an exemplary embodiment of the digital projection system.

### DETAILED DESCRIPTION

For the purposes of promoting an understanding of the principles of the present disclosure, reference will now be made to the embodiments illustrated in the drawings and the specific language used to describe the same. It should be understood that no limitation of the scope of this disclosure is thereby intended by these embodiments or descriptions.

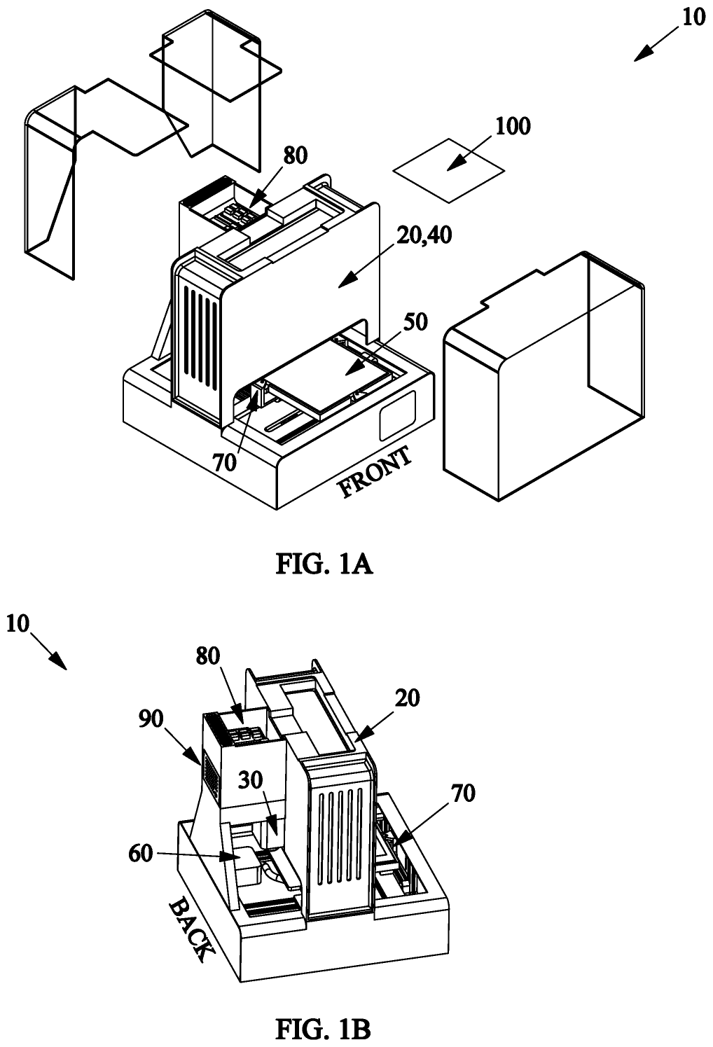

A novel digital projection system using a layer or series of layers of polymerized light sensitive material to build multi-dimensional structures is presented. Referring to FIGS. 1A and 1B, the system 10 is depicted. The system consists of, but is not limited to, at least one of the following subsystems: digital image projector 20, digital alignment camera 30, optics assembly 40, regulated heating coil 50, vacuum pump 60, linear stage 70, computer/controller with wired/wireless connectivity 80, power supply 90, and additional electronics required to operate the system for its intended purpose.

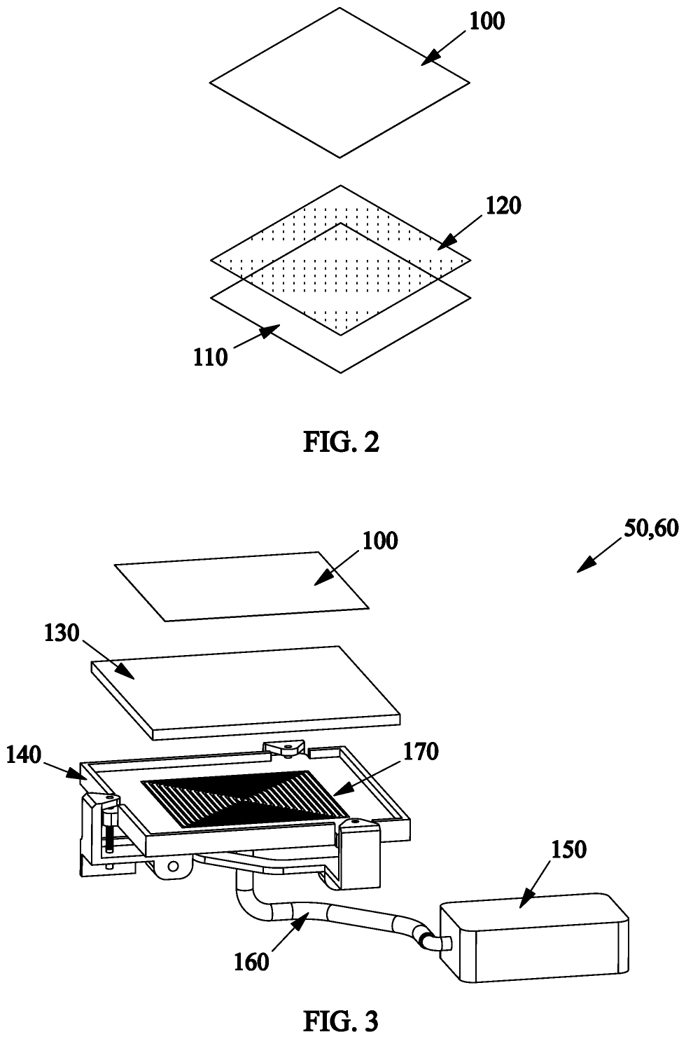

Prior to the polymerization of structures onto a substrate using digital images, a substrate is prepared for and initially bonded with a layer of light sensitive material. From here on the substrate bonded with a layer or multiple layers of light sensitive material will be referred to as “bonded substrate”. Referring to FIG. 2, the bonded substrate 100 is depicted. The substrate 110 is any rigid or flexible material forming the basis from which multi-dimensional structures can be built upon and consisting of a material compatible with the light sensitive material 120 bonded to it. The application of the layers of light sensitive material 120 onto the substrate 110 may include the use of spin-coating, used in conjunction with pre- or post-processing techniques, or the application of a dry films, used in conjunction with lamination and/or pre- or post-processing techniques.

Multi-dimensional design files created through the use computer aided design (CAD) are imported into a proprietary software package (not depicted in the figures) that interfaces with the digital projection system. The software package converts any multi-dimensional design into a single or series of digital images, arranging their alignments along a two-dimensional plane and/or in a series of successive layers. The software package provides the converted digital images, their arrangement/alignment, and an instruction set for the computer controlling the digital projection system's alignment camera, linear stage(s), and heating coil subsystems as a single file that is transferred either directly or indirectly over a wired/wireless connection.

Referring to FIG. 3, the vacuum pump subsystem 60 is depicted. The bonded substrate 100 is positioned and secured onto a porous platform 130 through the use of a vacuum applied to the base of the projection platform 140 from a vacuum pump 150 embedded in the base of the digital projection system and connected via a flexible hose 160. The operation of the vacuum pump 150 is automated by the digital projection system's computer/controller subsystem (80, FIG. 1) or manually by the system user through a manual override button incorporated in the system (additional electronics, not depicted). The applied vacuum prevents the movement of the bonded substrate 100 from the focal plane of digital image projector subsystem (20, FIG. 1) during the projection and polymerization process.

Referring to FIG. 3, the regulated heating coil subsystem 50 is depicted. At least one regulated heating coil 170, embedded within or underneath the porous platform 130, is used during the pre- and post-processing of the bonded substrate 100. During the pre-process, the bonded substrate 100 is heated to an optimal temperature, aiding in adhesion between the substrate and light sensitive material and preparing the light sensitive material for the projection and polymerization process. During the post-process, the bonded substrate 100 is heated to an optimal temperature, aiding in the completion of the projection and polymerization process of the light sensitive material. The heating coil subsystem 50, consisting of one or more heating coils 170, is energized or de-energized (regulated) by the digital projection system's computer/controller subsystem (80, FIG. 1) based on temperature readings of the porous platform 130 that are relayed to a temperature feedback system incorporated into the heat coil(s) subsystem (additional electronics, not depicted). The optimal temperature for pre- and post-processing is automated, selected by the interfacing software package based on the characteristics of bonded substrate 100 or manually by the user.

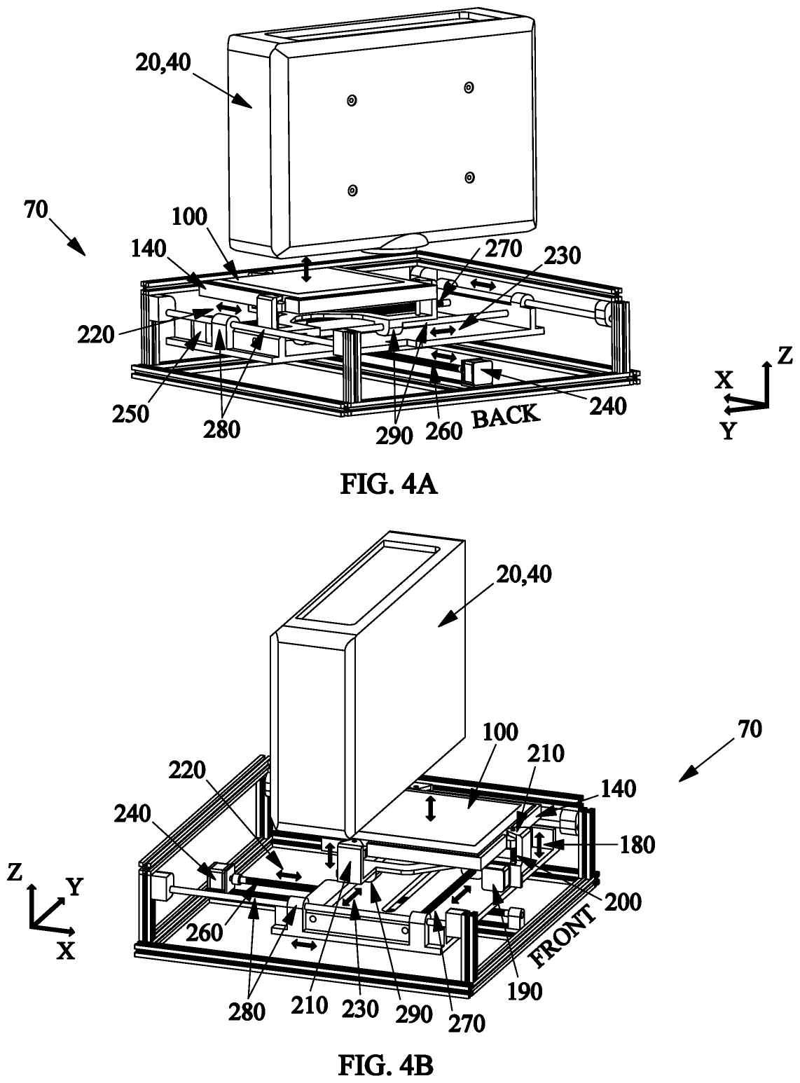

Referring to FIGS. 4A and 4B, the linear stage subsystem 70 is depicted. A normal linear stage 180, orientated normal to the focal plane of the digital projector system 20 and operating in the Z-Direction, is used to position the projection platform 140 such that the surface of the current layer of light sensitive material, bonded substrate 100 and secured to the projection platform 140, is in the focal plane of the of the digital projector subsystem 20. This normal linear stage consists of, but is not limited to, a motor 190, leadscrew 200, and alignment slide and guide rod 210. Power supplied by the digital projection system's power supply subsystem (90, FIG. 1) is regulated by the computer/controller subsystem (80, FIG. 1) and used to energize motor 190, rotating the leadscrew 200, and in turn moving the projection platform 140 up and down along the alignment slide and guide rod 210, acting normal to the focal plane of the digital projector system 20 in the Z-Direction. Adjustments to the projection platform 140 position with respect to the focal plane is further aided by an automated positioning process incorporating at least one digital alignment camera (30, FIG. 1) that images the surface of the bonded substrate 100 from which the linear stage's movements are then regulated by the digital projection system's computer/controller subsystem (80, FIG. 1) based on the captured images.

A set of parallel linear stages 220 & 230, parallel to the primary axes of the focal plane of the digital projector system 20 and operating in the X- & Y-Direction, are used to position the projection platform 140, with bonded substrate 100 secured to its surface, within the focal plane and at a location associated each digital image or images, as determined by the instruction set provided to the digital projection system 10 by the proprietary software package. Linear stages 220 (X-Direction) & 230 (Y-Direction) consists of, but are not limited to, motors 240 & 250, leadscrews 260 & 270, and alignment slides and guide rods 280 & 290, respectively. Power supplied by the digital projection system's power supply subsystem (90, FIG. 1) and regulated by the computer/controller subsystem (80, FIG. 1) is used to energize motors 240 & 250, rotating leadscrews 260 & 270, and in turn moving the projection platform 140 front and back (linear stage 220) and side-to-side (linear stage 230) along the alignment slide and guide rods 280 & 290, parallel to the focal plane of the digital projector system 20 in the X- & Y-Directions. The linear stages' movements are regulated by the digital projection system's computer/controller subsystem (80, FIG. 1) with or without position feedback in a closed-loop or open-loop configuration (additional electronics, not depicted), respectively.

The location of the projection platform's 140 parallel (linear stages 220 & 230) and normal (linear stages 180) position with respect to the primary axes of digital projector subsystem's 20 focal plane is associated with each digital image as determined by the instruction set provided by the proprietary software package and is from here on referred to as the “digital image alignment location”.

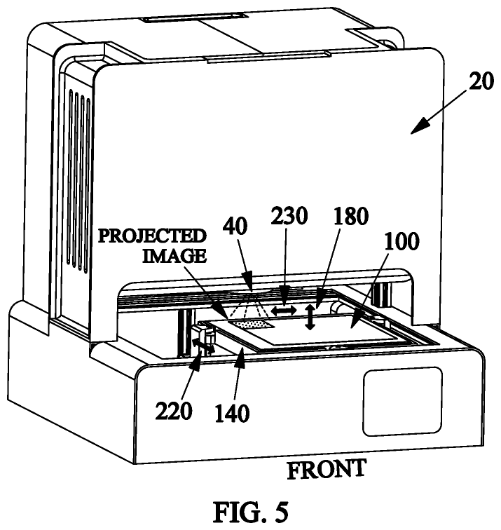

Referring to FIG. 5, the digital image alignment location and projection process is depicted. At each digital image alignment location, the projection platform 140 is moved into position by the parallel linear stages (220 & 230, FIGS. 4A & 4B) and normal linear stage (180, FIGS. 4A & 4B), the aperture of the digital image projector subsystem 20 is opened by the computer/controller subsystem (80, FIG. 1), projecting the digital image through the optics assembly subsystem 40 and onto the surface of the current layer of light sensitive material (120, FIG. 2) of the bonded substrate 100. Areas of the light sensitive material (120, FIG. 2) having been exposed to light within its activation bandwidth, begin to polymerize onto the substrate (110, FIG. 2), forming a layer of structures. The length of time in which areas of the light sensitive material are exposed to light from the digital projector subsystem is here on referred to as “exposure time”. After the optimal exposure time has elapsed, the computer/controller subsystem (80, FIG. 1) closes the digital image projector subsystem's 20 aperture, preventing further exposure of the current layer of light sensitive material (120, FIG. 2) of the bonded substrate 100. Optimal exposure times are included in the instruction set provided by the proprietary software package and are selected, either automatically or manually, by the software for a given substrate and light sensitive material.

The projection platform 140 is subjected to parallel movements by the linear stages described by item [0019] and normal movements by the linear stage described by item [0018] along the axes of digital image projector subsystem's 20 focal plane as directed by the computer/controller subsystem (80, FIG. 1), positioning the projection platform 140 at each digital image alignment location. At each digital image alignment location, areas of the light sensitive material are exposed in accordance to item [0021]. Thus, parallel movements and exposures within the focal plane of the digital image projector subsystem correspond to the polymerization of structures within the layer of light sensitive material of the bonded substrate 100, while movements and exposures normal to the focal plane of the digital image projector subsystem correspond to the polymerization of structures between layers of light sensitive material of the bonded substrate 100.

At the completion of the instruction set for the digital images provided to the digital projection system by the proprietary software package, the linear stages described by item [0018] and [0019] are used to return the projection platform 140 with bonded substrate 100 secured to its surface to the initial position of the digital projection system 10; at which point a post-process is preformed using the regulated heating coil subsystem as described by item [0017] and the bonded substrate is released from the projection platform 140 by deactivating of the vacuum pump subsystem as described by item

Once released, the bonded substrate 140 is then further post-processed in accordance with the type of light sensitive material (120, FIG. 1) and the polymerized multi-dimensional structures are used for their intended application.

1. A process by which a projection of a digital image or images are used to polymerize portions of a layer of light sensitive material onto a substrate.

2. A process by which the previous process in claim 1 is used in conjunction with a heating element in the pre- and post-processing of the light sensitive film onto a substrate.

3. A process by which multiple projections of digital images from the previous processes in claims 1 & 2 are arranged along the two parallel directions of the projector's focal plane, resulting in a larger polymerization area or multiple areas of a single layer of light sensitive film onto a substrate.

4. A process by which the previous processes in claim 1-3 are used to build successive layers of polymerized film forming multi-dimensional structures onto a substrate.

5. A digital projection system utilizing the previous processes in claim 1-4 and consisting of at least one of the following subsystems: digital projector, alignment camera, optics assembly, heating element, linear stage, control/computer with wired/wireless connectivity, and power supply.

6. Software capable of converting multi-dimensional designs into a single or series of images used by and interfacing with the system described in claim 5, transferred either directly or indirectly over a wired/wireless connection.

7. The digital projection system from claim 5 paired with post-processing procedures of the polymerized structures on a substrate for the development of device pertaining to, but not limited by, applications in printed circuit boards, microfluidics (lab-on-a-chip), or microchips fabrication.
